(19) United States
(12) Patent Application Publication
(10) Pub. No.: US 2026/0221007 A1
(43) Pub. Date: Jul. 30, 2026

(54) ELECTRONIC PAYMENT TERMINAL

(71) Applicant: BANKS AND ACQUIRERS INTERNATIONAL HOLDING, SURESNES (FR)

(72) Inventors: Bruno XAVIER, SURESNES (FR); Florence PANETTA, SURESNES (FR); Ferhaj CHOWDHARY, SURESNES (FR); Stéphane ESTORGES, SURESNES (FR); Herman NALBANT, SURESNES (FR)

(21) Appl. No.: 19/141,371

(22) PCT Filed: Dec. 22, 2023
(86) PCT No.: PCT/EP2023/087562

§ 371 Date: Jun. 20, 2025

(30) Foreign Application Priority Data
Dec. 23, 2022 (FR) FR2214365

(51) Int. Cl. G07G 1/00; H05K 9/00

(52) U.S. Cl. CPC G07G 1/0018; H05K 9/0067

(57) ABSTRACT

An electronic payment terminal including a display screen, an outer casing provided with an opening capable of generating electrostatic discharges in the direction of the screen, and a support for the screen with a housing for receiving the screen. The housing includes a discharge plate disposed between the screen and the opening. The discharge plate is configured to intercept an electrostatic discharge occurring between the opening and the screen.

### TECHNICAL FIELD

The invention relates to an electronic payment terminal.

### BACKGROUND

A payment terminal is already known in the state of the art. Such a terminal comprises an outer casing containing, inside it, at least one electronic card connected to various peripheral components for operating the terminal. In general, such an electronic card is connected to an input keyboard, a display screen, a smart or magnetic card reader . . . Usually, the electronic card is located at least partly under the input keyboard. Other peripheral components, such as a printer, a wireless communication module, etc., may also be provided. In general, the display screen is carried by a screen support. The outer casing has openings through which the keys of the input keyboard can pass. Because of these openings, and the contact of these openings with the user's skin, the display screen can be subjected to electrostatic discharges, which is harmful to the screen. Electrostatic discharges release energy that can damage the screen if it is in the path of the current at the time of the discharge, which may be the case if the electrostatic discharge occurs at an opening close to the screen. More specifically, when passing for example through a liquid crystal display, or “LCD” screen, such discharges can affect a matrix of dots, and generate white lines that appear on the screen. To protect the screen from electrostatic discharges, it is known to wrap the screen entirely in a shield, i.e. a metal envelope, enabling the screen to withstand electrostatic discharges. A shielded screen is said to be armoured. The shielded screen is carried by the screen support. However, shielding is associated with an increase in the cost of the screen.

### SUMMARY

In particular, the invention aims to provide an electronic payment terminal with a lower manufacturing cost, in which the screen is nevertheless protected from electrostatic discharges.

To this end, the invention relates to an electronic payment terminal comprising:
a display screen,
an outer casing provided with an opening capable of generating electrostatic discharges towards the screen,
a screen support comprising a housing for receiving the screen, characterised in that the housing comprises a discharge plate disposed between the screen and the opening, the discharge plate being configured to intercept an electrostatic discharge occurring between the opening and the screen.

The presence of the discharge plate enables the screen to resist electrostatic discharges, without the need for the screen to be shielded. This limits the use of metal, as shielding is generally made of metal, thus providing a payment terminal that is less expensive and uses less metal.

In addition, thanks to the discharge plate, and although the screen is not shielded, it is not necessary to provide a minimum distance between the screen and the opening in order to insulate the screen from electrostatic discharges. A terminal of this type therefore has no screen shield without being cumbersome.

Furthermore, in the context of contactless payment terminals, equipped with a communication antenna, it is known that the shield of the screen can produce significant interference at the antenna when it is in use. Being able to use a payment terminal without the need for the screen to be shielded is therefore of great interest in a contactless context and makes it possible to improve the contactless function. This configuration, which does not require shielding, also avoids disturbing other electronic components.

The term “opening capable of generating electrostatic discharges” is generally taken to mean an opening likely to come into contact with the user's skin, such as for example a button reception opening located next to the screen.

“The discharge plate being configured to intercept an electrostatic discharge occurring between the aperture and the screen” is generally understood to mean that the discharge plate is configured to intercept an electrostatic discharge generated by the aperture and which would pass through the screen in the absence of the discharge plate.

Depending on other optional features of the electronic payment terminal taken alone or in combination:
The display screen has no shielding. By “shielding” we mean a metallic discharge envelope that goes all the way round the screen.
The housing for the screen is delimited in particular by a plastic wall and the discharge plate is attached to this plastic wall.
   In this way, a pre-existing screen support is used, which also serves as a support for the discharge plate.

The plastic wall is advantageously arranged perpendicular to a main surface of the screen support, in a zone arranged between the screen and an input keyboard provided with at least one button passing through the opening arranged on the outer casing. The plastic wall comprises a surface on the screen side and a surface opposite this surface on the screen side. Advantageously, the discharge plate is arranged on the opposite surface. This means that it is not necessary to modify the housing in order to insert the discharge plate.
The display screen is located at a distance of less than or equal to 15 mm from the opening.
   Thanks to the invention, the electronic payment terminal can be used when the air is very dry. To protect the screen when the air is very dry, it is necessary to withstand electrostatic discharges of up to 15 kV. This corresponds to a distance between the opening and the screen of 15 mm.
The display screen is located at a distance of less than or equal to 8 mm from the opening.
   Thanks to the invention, the electronic payment terminal complies with standard IEC-61004-2 (Testing and measurement techniques-Electrostatic discharge immunity test), which stipulates that electronic components must not be subjected to an electrostatic discharge greater than 8 kV, which corresponds to a distance of 8 mm between the generation of an electrostatic discharge and the electronic component.
The discharge plate is a metal part, grounded.
   The discharge plate diverts electrostatic discharges, preventing them from passing into the screen.
   The discharge plate is, for example, a solid plate. It can also be perforated. It is understood that the discharge plate is made of a conductive metal. Advantageously, it is made of stainless steel. Stainless steel ½ H has a particularly suitable hardness, as it must be sufficiently flexible and deformable to set up the connection with the ground.
The grounded discharge plate is connected to a shield of the electronic card.
   The shield of the circuit card is connected to ground, providing a link between the discharge plate and ground. This configuration is simple because the electronic card shield is located in the screen support, between the electronic card and the screen. In this way, the discharge plate is connected to a part connected to ground and located close to the discharge plate.
   Alternatively, the discharge plate can be connected to the electronic card, which has the same advantage.
The discharge plate includes a tab intended to make contact with the ground.
   Contact with ground is made via the tab. The tab extends from the discharge plate to to make contact. It is thus possible to establish a connection to ground at a site that is remote from the plate.
   Advantageously, the tab is movable relative to the discharge plate and is deformable. Preferably, the tab is elastic so that the elastic return force tends to establish contact. In this way, contact is ensured, whatever the manufacturing and assembly tolerances of the parts. Advantageously, the tab extends from a lower edge of the discharge plate, when the latter is positioned in the electronic payment terminal, and occupies a central position relative to the lower edge of the discharge plate. In this way, the tab allows the connection with a grounded part located in the direction of the electronic card.
The plastic wall comprises a surface on the screen side and a surface opposite this surface on the screen side, and the discharge plate is arranged on the opposite surface, and the plastic wall comprises a passage for the tab.
   In this way, the tab can pass through the plastic wall to ensure ground contact of the discharge plate. This configuration allows the ground connection to be made on the other side of the plastic wall, on the screen side. In this way, for example, the discharge plate can be connected to a shield of the electronic card.
The discharge plate has a thickness of between 0.05 and 0.5 mm, preferably around 0.1 mm.
   Such a thickness is compatible with the function of the discharge plate, and allows the tab to have sufficient flexibility to make contact with the ground. It is advantageous for the plate to have a thickness close to 0.1 mm to reduce the amount of metal.
The discharge plate is fixed to the plastic wall by heading. This method of attachment is particularly suitable for attaching a metal part to a plastic part. It is also used to attach other components to the screen support, such as an antenna when the payment terminal can be used without contact. It is therefore advantageous to use the same attachment technique for the discharge plate. Alternatively, the discharge plate could be attached by gluing, clipping, screwing or any other attachment method known to the person skilled in the art.
The payment terminal is equipped with a communication antenna for contactless use.

### BRIEF DESCRIPTION OF THE FIGURES

The invention will be better understood on reading the following description, which is given by way of example only and with reference to the attached drawings in which:

FIG. 1 is an exploded perspective view of a payment terminal according to the invention;

FIG. 2 is a detail view of the circled part of FIG. 1, showing in particular the display screen and the screen support;

FIG. 3 is a view of the detail in FIG. 2, in a different orientation to FIG. 2, in which the discharge plate has been removed;

FIG. 4 is a perspective view of the payment terminal screen shown in FIG. 1;

FIG. 5 is a perspective view of the assembly formed by the electronic card, its shielding and the discharge plate of the payment terminal shown in FIG. 1;

FIG. 6 is a rear view of the discharge plate of the payment terminal shown in FIG. 1;

FIG. 7 is a side view of the assembly shown in FIG. 5.

### DETAILED DESCRIPTION

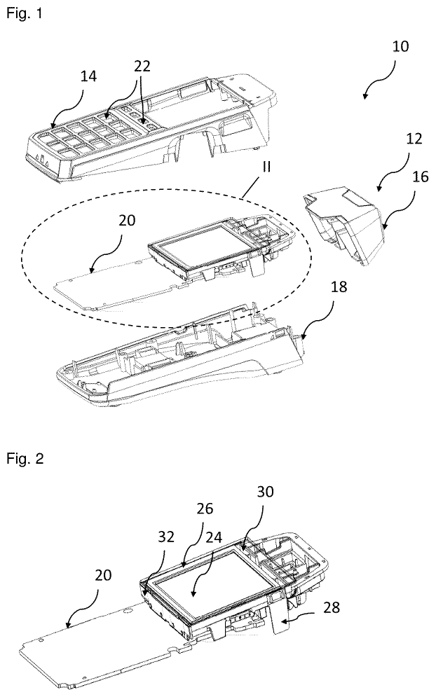

FIG. 1 shows a payment terminal according to the invention, designated by the general reference 10. The terminal 10 comprises an outer casing 12 consisting of an upper part 14, a rear part 16 and a lower part 18. Inside the casing 12, the terminal 10 comprises an electronic card 20 connected to components for operating the terminal 10, such as an input keyboard comprising keys, not shown, and openings 22 in the casing 12. The openings 22 are located in the upper part 14 of the casing 12, next to the screen 24. The terminal 10 also comprises, inside the casing 12, a display screen 24, also connected to the electronic card 20. The electronic card 20 is located partly below the input keyboard and below the screen 24.

The display screen 24, visible in particular in FIG. 4, is an LCD screen. It is made up of electronic components enabling the display, and an envelope which goes all the way round the screen 24, and enables the electronic components to be held in place. The envelope comprises several layers of plastic. The screen 24 has no shielding, i.e. the electronic components of the screen 24 are not in a metallic discharge envelope.

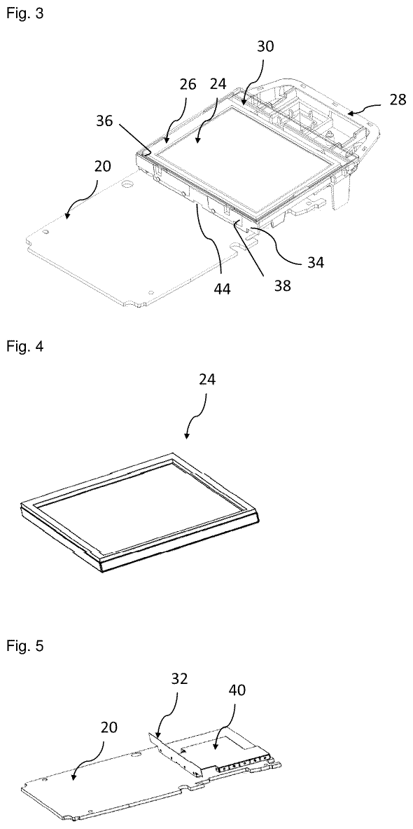

The screen 24 is protected by a glass pane 26, located above the screen 24. The display screen 24 is carried by a screen support 28, shown in particular in FIGS. 2 and 3. The screen support 28 is made of a plastic material, more particularly ABS (acrylonitrile-butadiene-styrene). The screen support 28 has a housing 30 for receiving the screen 24. The housing 30 comprises a discharge plate 32, visible in FIGS. 2 and 5 to 7.

Each opening 22 in the casing 12 is likely to generate electrostatic discharges towards the screen 24. This is because opening 22 is likely to be in contact with the user's skin. The discharge plate 32 is positioned between the screen 24 and the opening 22. The discharge plate 32 is configured to intercept an electrostatic discharge occurring between the opening 22 and the screen 24.

The housing 30 for receiving the screen 24 is delimited in particular by a plastic wall 34, visible in particular in FIG. 3, in which the discharge plate 32 has been removed, and the discharge plate 32 is attached to this plastic wall 34, as visible in FIG. 2. The plastic wall 34 is arranged perpendicularly to a main surface of the screen support 28, in a region arranged between the screen 24 and an input keyboard provided with at least one button, not shown, passing through the opening 22 arranged on the outer casing 12. The plastic wall 34 comprises a surface 36 located on the side of the screen 24 and a surface 38 opposite this surface 36 on the side of the screen 24 (shown in particular in FIG. 3). The discharge plate 32 is arranged on the opposite surface 38.

The display screen 24 is located at a distance from the aperture 22 of less than 15 mm, also less than 8 mm.

The discharge plate 32 is a grounded metal part. Discharge plate 32 is a solid plate. It could also be apertured. It is made of a conductive metal, specifically ½ stainless steel, but another conductive metal could be suitable.

The terminal 10 also includes a shield 40 for the electronic card 20, visible in FIGS. 5 and 7. The discharge plate 32 is connected to the shield 40, which ensures its connection to ground. The discharge plate could be connected to another grounded component, such as the electronic card 20.

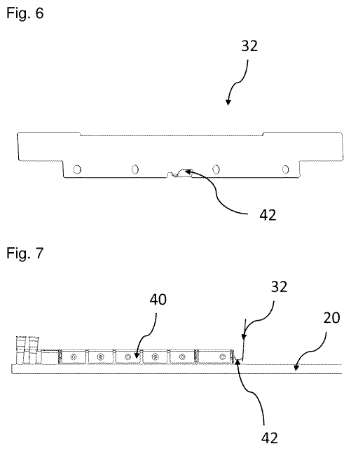

As can be seen in FIGS. 6 and 7, which the discharge plate 32 comprises a tab 42 for making contact with the ground. The tab 42 extends from the discharge plate 32 so as to make contact with the ground. The tab 42 is movable relative to the discharge plate 32 and is deformable. The tab 42 is elastic so that the elastic return force tends to establish contact. In this way, contact is ensured, whatever the manufacturing and assembly tolerances of the parts. The tab 42 starts from a lower edge of the discharge plate 32, when the latter is positioned in the electronic payment terminal 10, and occupies a central position with respect to the lower edge of the discharge plate 32.

The plastic wall 34 includes a passage 44, visible in FIG. 3, for the tab 42. In this way, the tab 42 can pass through the plastic wall 34 to ensure ground contact of the discharge plate 32. This configuration enables the ground connection to be made on the other side of the plastic wall 34, on the side of the screen 24. The discharge plate 32 can thus be connected to the shield 40 of the electronic card 20.

The discharge plate 32 is approximately 0.1 mm thick.

The discharge plate 32 is fixed to the plastic wall 34 by heading. This method of attachment is used to attach other components to the screen support 28, such as an antenna, not shown, when the payment terminal 10 can be used without contact. It is therefore advantageous to use the same attachment technique to fix the discharge plate 32. Alternatively, the discharge plate 32 could be fixed by gluing, clipping, screwing or any other attachment method known to the person skilled in the art.

The invention is not limited to the embodiments shown, and other embodiments will become apparent to the person skilled in the art. In particular, it is possible for the opening likely to generate electrostatic discharges to be a separate opening from an opening for receiving a button, provided that said opening is likely to generate electrostatic discharges towards the screen.

### List of References

10: electronic payment terminal
12: outer casing
14: upper part of the casing
16: back of casing
18: lower part of the casing
20: electronic card
22: opening
24: display screen
26: glass pane
28: screen support
30: screen housing
32: discharge plate
34: housing boundary wall
36: surface of the wall on the screen side
38: surface opposite the surface on the screen side
40: shield of the electronic card
42: discharge plate tab
44: passage in the wall

1. An electronic payment terminal comprising:
a display screen,
an outer casing provided with an opening capable of generating electrostatic discharges towards the screen, and
a support for the screen comprising a housing for receiving the screen,
wherein that the housing comprises a discharge plate disposed between the screen and the opening, the discharge plate being configured to intercept an electrostatic discharge generated by the opening and which would pass through the screen in the absence of the discharge plate.

2. The electronic payment terminal according to claim 1, wherein the display screen has no shielding.

3. The electronic payment terminal according to claim 1, wherein the housing for receiving the screen is delimited by a wall made of plastic and the discharge plate is attached to the wall made of plastic.

4. The electronic payment terminal according to claim 1, wherein the display screen is located at a distance from the opening less than or equal to 15 mm.

5. Electronic The electronic payment terminal according to claim 4, wherein the display screen is located at a distance from the opening less than or equal to 8 mm.

6. The electronic payment terminal according to claim 1, wherein the discharge plate is a part of metal and is grounded.

7. The electronic payment terminal according to claim 6, wherein the grounded discharge plate is connected to a shield of an electronic card.

8. The electronic payment terminal according to claim 7, wherein the discharge plate comprises a tab intended to make contact with the ground.

9. The electronic payment terminal according to claim 8, wherein:
the housing for receiving the screen is delimited by a plastic wall and the discharge plate is attached to the plastic wall,
the plastic wall comprises a surface located on a side of the screen and a surface opposite this surface on the side of the screen, and
the discharge plate is arranged on the opposite surface, and
the plastic wall comprises a passage for the tab.

10. The electronic payment terminal according to claim 8, wherein the discharge plate has a thickness ranging from 0.05 to 0.5 mm.

11. The electronic payment terminal according to claim 10, wherein the housing for receiving the screen is delimited by a plastic wall and the discharge plate is attached to the plastic wall, and the discharge plate is fixed to the plastic wall by heading.

12. The electronic payment terminal according to claim 1, the payment terminal being equipped with a communication antenna for contactless use.

13. The electronic payment terminal according to claim 6, wherein the discharge plate comprises a tab intended to make contact with the ground.

14. The electronic payment terminal according to claim 13, wherein:
the housing for receiving the screen is delimited by a plastic wall and the discharge plate is attached to the plastic wall,
the plastic wall comprises a surface located on a side of the screen and a surface opposite this surface on the side of the screen, and
the discharge plate is arranged on the opposite surface, and
the plastic wall comprises a passage for the tab.

15. The electronic payment terminal according to claim 14, wherein the discharge plate has a thickness ranging from 0.05 to 0.5 mm.

16. The electronic payment terminal according to claim 14, wherein the discharge plate has a thickness of 0.1 mm.

17. The electronic payment terminal according to claim 8, wherein the discharge plate has a thickness of 0.1 mm.
